(19) United States
(12) Patent Application Publication
(10) Pub. No.: US 2023/0386451 A1
(43) Pub. Date: Nov. 30, 2023

(54) VOICE WAKEUP DETECTING DEVICE AND METHOD

(71) Applicant: MEDIATEK INC., Hsinchu City (TW)

(72) Inventors: Liang-Che SUN, Hsinchu City (TW); Yiou-Wen CHENG, Hsinchu City (TW)

(21) Appl. No.: 17/825,250

(22) Filed: May 26, 2022

(51) Int. Cl. G10L 15/08; H04R 3/04; H03M 1/12

(52) U.S. Cl. CPC G10L 15/08; H04R 3/04; H03M 1/123; G10L 2015/088; H04R 2430/01

(57) ABSTRACT

Voice wakeup detecting devices and methods are provided. A microphone is configured to receive an audio input signal. The audio input signal includes a voice signal and an ambient voice signal. A first analog-to-digital converter is configured to convert the audio input signal into a first signal according to a first gain. A second analog-to-digital converter is configured to convert the audio input signal into a second signal according to a second gain. A control module is configured to merge the first signal multiplied by first weight and the second signal multiplied by second weight into a third signal and to adjust the first weight and the second weight in response to a volume value. The second gain is less than the first gain, and the first weight is different than the second weight.

### BACKGROUND OF THE INVENTION

### Field of the Invention

The invention relates to a voice wakeup detecting device, and more particularly to a voice wakeup detecting device with a high dynamic range.

### Description of the Related Art

Nowadays, the functions of smartphones are diverse. For example, smartphones with a voice wakeup function are favored by most consumers. When a smartphone detects the user's voice speaking a keyword while in sleep mode, the smartphone is able to recognize the keyword. If a keyword is detected, the smartphone switches from sleep mode to a normal mode. In other words, the user can wake up the smartphone or another electronic device without having to press a function key on the device.

A voice recognition function is always applied to a portable device (such as a mobile phone) so that a user can use voice commands (i.e., a speech signal) to activate the portable device or to control the portable device to perform some function. However, in order to detect the voice, the microphone of the portable device needs to be always turned on. Moreover, the voice wakeup detecting module of the portable device also must always be turned on if it is to recognize the received voice. Thus, the power consumption by the portable device is increased due to the voice recognition function.

### BRIEF SUMMARY OF THE INVENTION

Voice wakeup detecting devices and methods are provided. An embodiment of a voice wakeup detecting device is provided. The voice wakeup detecting device includes a microphone, a first analog-to-digital converter (ADC), a second analog-to-digital converter and a control module. The microphone is configured to receive an audio input signal, wherein the audio input signal includes a voice signal and an ambient voice signal. The first analog-to-digital converter is configured to convert the audio input signal into a first signal according to a first gain. The second analog-to-digital converter is configured to convert the audio input signal into a second signal according to a second gain. The control module is configured to merge the first signal multiplied by a first weight and the second signal multiplied by a second weight into a third signal. The control module is also configured to adjust the first weight and the second weight in response to a volume value. The second gain is less than the first gain, and the first weight is different than the second weight.

Furthermore, an embodiment of a voice wakeup detecting device is provided. The voice wakeup detecting device includes a speaker, a microphone, a control module, and an analog-to-digital converter (ADC). The microphone is configured to receive an audio input signal, and the audio input signal includes a voice signal and an ambient voice signal. The speaker is configured to provide an audio output signal as at least a part of the ambient voice signal. The control module is configured to provide a variable gain in response to a volume value of the audio output signal. The analog-to-digital converter is configured to convert the audio input signal into a first signal according to the variable gain having a first gain value when the output volume value is less than or equal to a first threshold value. The control module is configured to provide a second signal according to the first signal corresponding to the first gain value.

Moreover, an embodiment of a voice wakeup detecting method for detecting a wake-word is provided. An audio input signal is obtained via a microphone, and the audio input signal includes a voice signal and an ambient voice signal. A first weight and a second weight are obtained in response to a volume value. The audio input signal is converted into a first signal according to a first gain, and the first signal is multiplied by the first weight. The audio input signal is converted into a second signal according to a second gain, and the second signal is multiplied by the second weight. The first signal multiplied by the first weight and the second signal multiplied by the second weight are merged to obtain a third signal. The third signal is analyzed to determine whether voice representation of the wake-word is present in the third signal. The first gain is greater than the second gain.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a voice wakeup detecting device according to some embodiment of the invention.

FIG. 2 shows a voice wakeup detecting method for detecting a wake-word according to some embodiment of the invention.

FIG. 3 shows a voice wakeup detecting device according to some embodiment of the invention.

FIG. 4 shows a voice wakeup detecting method for detecting a wake-word according to some embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

Some variations of the embodiments are described. Throughout the various views and illustrative embodiments, like reference numbers are used to designate like elements. It should be understood that additional operations can be provided before, during, and/or after a disclosed method, and some of the operations described can be replaced or eliminated for other embodiments of the method.

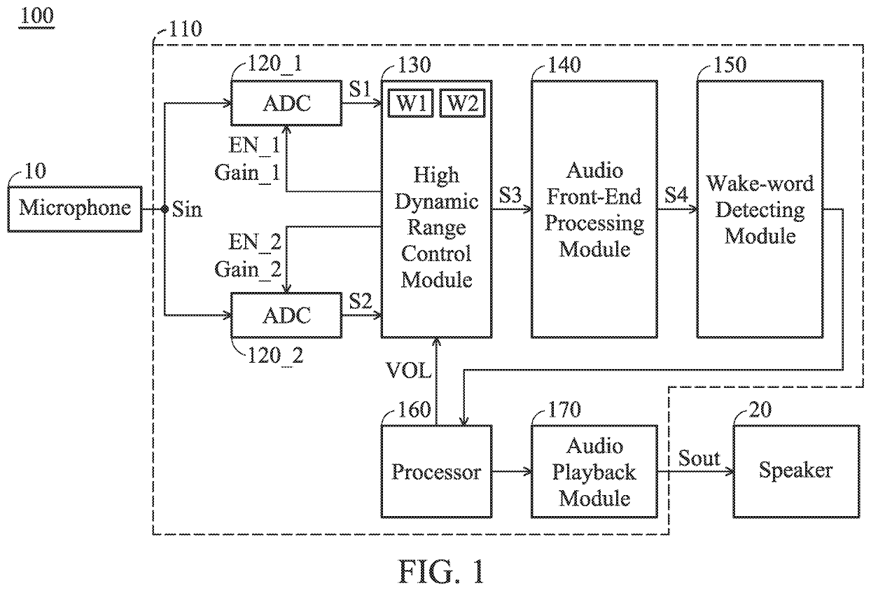

FIG. 1 shows a voice wakeup detecting device 100 according to some embodiment of the invention. The voice wakeup detecting device 100 is a portable device powered by a battery (not shown). In some embodiments, the voice wakeup detecting device 100 is a mobile phone, a wearable device (e.g., wireless headset, smart watch) and so on. The voice wakeup detecting device 100 includes a microphone 10, an audio processing circuit 110 and a speaker 20. The microphone 10 is configured to transduce sound received at the microphone 10 into an audio input signal Sin. The speaker 20 is configured to provide (or play) an audio output signal Sout with a volume value VOL. In some embodiments, the voice wakeup detecting device 100 is configured to generate the audio output signal Sout according to audio information of multimedia data (or file). When the output volume value VOL is too loud, the audio output signal Sout played by the speaker 20 may be received by the microphone 10. When the distance between the speaker 20 and the microphone 10 is close, the audio output signal Sout received by the microphone 10 is increased. In such embodiment, the audio input signal Sin corresponding to the sound received at the microphone 10 may include a voice signal from a user and an ambient voice signal (e.g., the audio output signal Sout played by the speaker 20). In order to simplify the description, other circuits and components within the voice wakeup detecting device 100 are omitted.

The audio processing circuit 110 includes the analog-to-digital converters (ADC) 120_1 and 120_2, a high dynamic range control module 130, an audio front-end processing module 140, a wake-word detecting module 150, a processor 160 and an audio playback module 170. The components and modules within the audio processing circuit 110 can be implemented in one or more integrated circuits (ICs). The processor 160 is configured to control the audio playback module 170 to provide the audio output signal Sout, so as to play the audio output signal Sout with the output volume value VOL via the speaker 20. In some embodiments, the audio playback module 170 provides the audio output signal Sout according to the multimedia data stored in a storage device (not shown) of the voice wakeup detecting device 100 or the multimedia data obtained wirelessly.

The high dynamic range control module 130 is configured to provide the signal EN_1 and the gain Gain_1 to the analog-to-digital converter 120_1 and provide the signal EN_2 and the gain Gain_2 to the analog-to-digital converter 120_2. When the analog-to-digital converter 120_1 is enabled by the signal EN_1, the analog-to-digital converter 120_1 is configured to convert the audio input signal Sin from the microphone 10 into the signal S1 according to a gain Gain_1. Similarly, when the analog-to-digital converter 120_2 is enabled by the signal EN_2, the analog-to-digital converter 120_2 is configured to convert the audio input signal Sin from the microphone 10 into the signal S2 according to a gain Gain_2. In other words, the analog-to-digital converter 120_1 provides a first signal processing path for the audio input signal Sin, and the analog-to-digital converter 120_2 provides a second signal processing path for the audio input signal Sin. In some embodiments, the first signal processing path is assigned to amplify the audio input signal Sin in a non-playing mode or a low-volume playing mode, and the second signal processing path is assigned to amplify the audio input signal Sin in a high-volume playing mode. In some embodiments, the analog-to-digital converters 120_1 and 120_2 are the 16-bit analog-to-digital converters having the same circuit configurations, and each of the signals S1 and S2 is 16-bit digital signal including one sign bit and fifteen magnitude bits.

The gain Gain_1 and gain Gain_2 are set by the high dynamic range control module 130, and the gain Gain_1 is greater than the gain Gain_2. In some embodiments, the gain Gain_1 and the gain Gain_2 are fixed. For example, the gain Gain_1 is set to 18 dB, and the gain Gain_2 is set to 0 dB. In some embodiments, the gain Gain_1 and the gain Gain_2 are variable, and the high dynamic range control module 130 is configured to provide the variable gain Gain_1 and the variable Gain_2 in response to the output volume value VOL of the audio output signal Sout. In some embodiments, the gain Gain_2 is fixed and the gain Gain_1 is variable, and when the output volume value VOL exceeds the threshold value VOLth_out, the high dynamic range control module 130 is configured to decrease the gain Gain_1.

After obtaining the signals S1 and S2, the high dynamic range control module 130 is configured to multiply the signal S1 with a first weight W1 and multiply the signal S2 with a second weight W2, and to merge the signal S1 multiplied by the first weight W1 and the signal S2 multiplied by the second weight W2 into the signal S3. In some embodiments, the signals S1 and S2 are recorded in the high dynamic range control module 130. Furthermore, the high dynamic range control module 130 is configured to multiply the recorded signal S1 with the first weight W1 and multiply the recorded signal S2 with the second weight W2.

In some embodiments, the first weight W1 or the second weight W2 is the real part number applied in time domain for the signals S1 and S2. In some embodiments, the first weight W1 or the second weight W2 is the complex weight applied to a specific frequency sub-band for the signals S1 and S2. That is, the human speech typically covers frequencies from 30 to 10,000 Hz, and most of the energy is in the range from 200 to 3500 Hz. The complex weight may apply different values in different voice frequency domain. For example, 30% is applied on 200 to 500 Hz sub-band, 80% is applied on 500 to 1800 Hz, 20% is applied on 1800 to 2500 Hz. By applying different weighted values to the frequency sub-band, the speech voice could be captured more clearly.

In some embodiments, the first weight W1 and the second weight W2 are fixed. In some embodiments, the first weight W1 and the second weight W2 are variable. For example, when the output volume value VOL is equal to 0 (i.e., no audio output signal Sout is played), the first weight W1 and the second weight W2 are fixed. When the output volume value VOL is greater than 0 (i.e., the audio output signal Sout is played via the speaker 20), the high dynamic range control module 130 is configured to adjust the first weight W1 and the second weight W2 in response to the output volume value VOL. When the output volume value VOL is less than or equal to a threshold value VOLth_out, the high dynamic range control module 130 is configured to adjust the first weight W1 and second weight W2 (e.g., increasing the first weight W1 and decreasing the second weight W2), so that the first weight W1 is greater than the second weight W2. Conversely, when the output volume value VOL is greater than the threshold value VOLth_out, the high dynamic range control module 130 is configured to adjust the first weight W1 and second weight W2 (e.g., decreasing the first weight W1 and increasing the second weight W2), so that the first weight W1 is less than the second weight W2. In other words, by adjusting the first weight W1 and the second weight W2, the composition ratio of the signal S1 and the signal S2 in the signal S3 is changed.

When the output volume value VOL does not exceed the threshold value VOLth_out (e.g., no audio output signal Sout is played or the audio output signal Sout is played with a small volume), the first weight W1 is greater than the second weight W2, and the signal S3 is mainly composed of the signal S1. Conversely, when the output volume value VOL exceeds the threshold value VOLth_out, the first weight W1 is less than the second weight W2, and the signal S3 is mainly composed of the signal S2.

As described above, the gain Gain_1 is greater than the gain Gain_2, so the signal S1 has larger amplitude than the signal S2. When the audio input signal Sin has larger amplitude, the signal S1 provided by the analog-to-digital converter 120_1 may be clipped (or saturated). Therefore, by using lower first weight W1 for the signal S1, distortion of the signal S3 can be avoided when the audio input signal Sin has larger amplitude.

The audio front-end processing module 140 is configured to perform optimization operations (e.g., beamforming, noise reduction (NR), acoustic echo cancellation (AEC)) on the signal S3 to obtain the signal S4. The wake-word detecting module 150 is configured to analyze the signal S4 to determine whether voice representation of a wake-word is present in the signal S4. The wake-word is a wake-up word for performing a specific application or operation, such as voice assistant. When the wake-word is recognized by the wake-word detecting module 150, the wake-word detecting module 150 is configured to notify the processor 160 so as to perform the corresponding applications or operations.

In the voice wakeup detecting device 100, the audio input signal Sin is amplified by using multiple 16-bit analog-to-digital converters (e.g., 120_1 and 120_2) with different gains (e.g., Gain_1 and Gain_2). Compared with the traditional voice wakeup detecting device having a single analog-to-digital converter with fixed gain, the high dynamic range control module 130 is capable of providing a high dynamic range signal processing on the audio input signal Sin by using the corresponding weights for different analog-to-digital converters. Therefore, the voice wakeup detecting device 100 can perform a barge-in operation (i.e., wake-up during playback) more accurately without using a power-hungry high dynamic range analog-to-digital converter.

In some embodiments, the voice wakeup detecting device 100 has multiple speakers 20 and/or multiple microphone 10 located at different locations on the voice wakeup detecting device 100. For the audio input signal Sin from each microphone 10, the high dynamic range control module 130 is configured to obtain the first weight W1 and second weight W2 according to the volume values VOL of whole speakers 20.

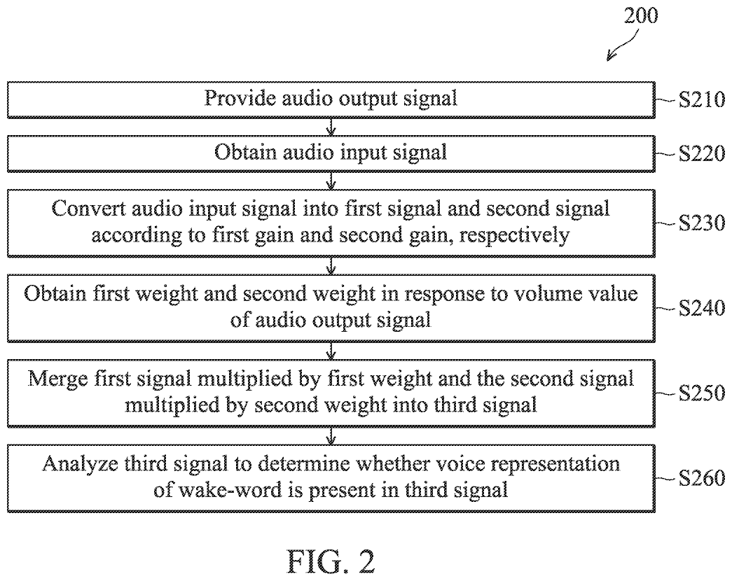

FIG. 2 shows a voice wakeup detecting method 200 for detecting a wake-word according to some embodiment of the invention. The voice wakeup detecting method 200 of FIG. 2 is performed by an electronic device (e.g., the voice wakeup detecting device 100 of FIG. 1) having multiple signal processing paths for an audio input signal, and each signal processing path is provided by the respective analog-to-digital converter (e.g., the analog-to-digital converters 120_1 and 120_2 of FIG. 1). In some embodiments, the electronic device is powered by a battery.

In step S210, the electronic device is configured to operate in a playing mode, so as to provide (or play) an audio output signal Sout with a volume value VOL via at least one speaker.

In step S220, the electronic device is configured to obtain an audio input signal Sin via a microphone in the playing mode. As described above, the audio input signal Sin may include a voice signal from a user and the audio output signal Sout played by the speaker.

In step S230, the audio input signal Sin is converted into the signal S1 with the gain Gain_1 and the signal S2 with the gain Gain_2 via the respective analog-to-digital converters, respectively. As described above, the gain Gain_1 in the first signal processing path is greater than the gain Gain_2 in the second signal processing path. In some embodiments, the gain Gain_1 and the gain Gain_2 are fixed. In some embodiments, the gain Gain_1 and the gain Gain_2 can be adjusted with the output volume value VOL of the audio output signal Sout. In some embodiments, the gain Gain_2 is fixed and the gain Gain_1 is variable, and when the output volume value VOL exceeds the threshold value VOLth_out, the gain Gain_1 is decreased.

In step S240, the first weight W1 and the second weight W2 are obtained according to the output volume value VOL of the audio output signal Sout. In some embodiments, the first weight W1 is greater than the second weight W2 when the output volume value VOL is less than or equal to a threshold value VOLth_out, and the first weight W1 is less than the second weight W2 when the output volume value VOL is greater than the threshold value VOLth_out. In some embodiments, the first weight W1 may be decreased and the second weight W2 may be increased when the output volume value VOL exceeds the threshold value VOLth_out, and the first weight W1 may be increased and the second weight W2 may be decreased when the output volume value VOL does not exceed the threshold value VOLth_out. In some embodiments, the order of steps S230 and S240 in the voice wakeup detecting method 200 can be interchanged.

In step S250, the signal S1 obtained in the first signal processing path is multiplied by the first weight W1 and the signal S2 obtained in the second signal processing path is multiplied by the second weight W2. Next, the signal S1 multiplied by the first weight W1 and the signal S2 multiplied by the second weight W2 are merged to obtain the signal S3.

In step S260, the signal S3 is analyzed to recognize whether voice representation of wake-word is present in the signal S3. In some embodiments, before analyzing the signal S3, one or more pre-processing operations (e.g., NR and AEC) are performed on the signal S3 so as to improve the wake-word recognition rate.

If the voice representation of wake-word is recognized, it is determined that the audio input signal Sin corresponding the wake-word is received by the electronic device, and then the operation corresponding to the wake-word is performed by the electronic device.

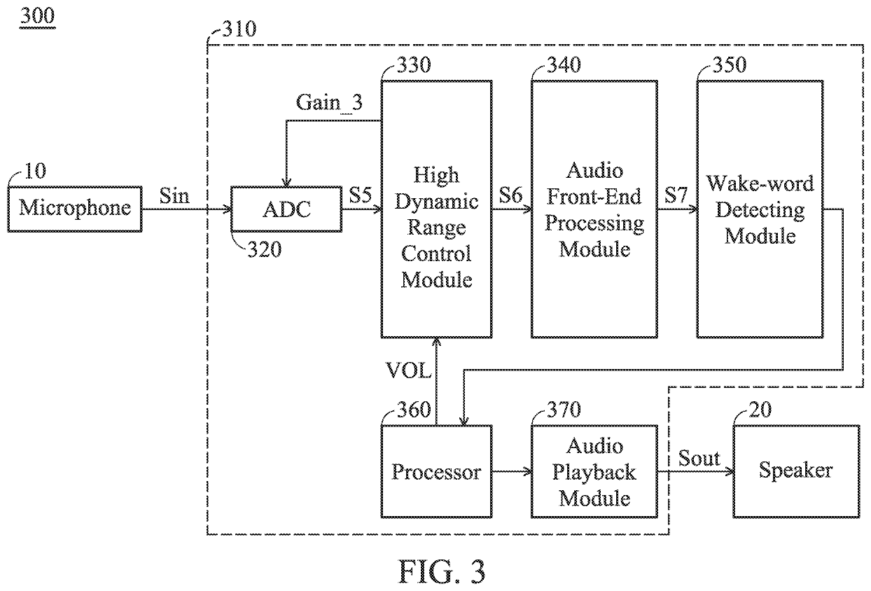

FIG. 3 shows a voice wakeup detecting device 300 according to some embodiment of the invention. The voice wakeup detecting device 300 is a portable device 300 powered by a battery (not shown). In some embodiments, the voice wakeup detecting device 300 is a mobile phone, a wearable device (e.g., wireless headset, smart watch) and so on. The voice wakeup detecting device 300 includes a microphone 10, an audio processing circuit 310 and a speaker 20. In order to simplify the description, other circuits and components within the voice wakeup detecting device 300 are omitted.

The audio processing circuit 310 includes the analog-to-digital converter 320, a high dynamic range control module 330, an audio front-end processing module 340, a wake-word detecting module 350, a processor 360 and an audio playback module 370. Compared with the audio processing circuit 110 of FIG. 1, the audio processing circuit 310 of FIG. 3 only includes the single analog-to-digital converter 320. In some embodiments, the analog-to-digital converter 320 is the 16-bit analog-to-digital converter, and the signal S5 is 16-bit digital signal including one sign bit and fifteen magnitude bits. The components and modules within the audio processing circuit 310 can be implemented in one or more ICs.

The processor 360 is configured to control the audio playback module 370 to provide the audio output signal Sout, so as to play the audio output signal Sout with the output volume value VOL via the speaker 20. The analog-to-digital converter 320 is configured to convert the audio input signal Sin from the microphone 10 into the signal S5 according to a gain Gain_3, and the gain Gain_3 is variable. The high dynamic range control module 330 is configured to provide the gain Gain_3 to the analog-to-digital converter 320 in response to the output volume value VOL of the audio output signal Sout.

When the output volume value VOL is less than or equal to a threshold value VOLth_out, the high dynamic range control module 330 is configured to set the gain Gain_3 has a higher gain value (e.g., 18 dB). Conversely, when the output volume value VOL is greater than the threshold value VOLth_out, the high dynamic range control module 330 is configured to set the gain Gain_3 has a lower gain value (e.g., 0 dB). In some embodiments, the default value of the gain Gain_3 is a higher gain value (e.g., 18 dB). In some embodiments, the high dynamic range control module 330 includes a timer (not shown) that is configured to count a specific time period. When the signal S5 has a higher volume value (e.g., exceeds a threshold value VOLth_in) for the specific time period (e.g., ≥1 second), the high dynamic range control module 330 is configured to set the gain Gain_3 has a lower gain value. Furthermore, when the volume value of the signal S5 does not exceed the threshold value VOLth_in, the high dynamic range control module 330 is configured to set the gain Gain_3 has a higher gain value.

Furthermore, the high dynamic range control module 330 is further configured to provide the signal S6 to the audio front-end processing module 340 according to the signal S5. The audio front-end processing module 340 is configured to perform optimization operations (e.g., beamforming, NR. AEC and so on) on the signal S6 to obtain the signal S7. The wake-word detecting module 350 is configured to analyze the signal S7 to determine whether voice representation of a wake-word is present in the signal S7. When the wake-word is recognized by the wake-word detecting module 350, the wake-word detecting module 350 is configured to notify the processor 360 so as to perform the corresponding application or operation.

In the voice wakeup detecting device 300, the audio input signal Sin is amplified by using the single 16-bit analog-to-digital converter with variable gain. Compared with the traditional voice wakeup detecting device having the analog-to-digital converter with fixed gain, the high dynamic range control module 330 is capable of providing a high dynamic range signal processing on the audio input signal Sin by using the different gains corresponding to the output volume value VOL. Therefore, the voice wakeup detecting device 300 can perform a barge-in operation (i.e., wake-up during playback) more accurately without using a power-hungry high dynamic range analog-to-digital converter.

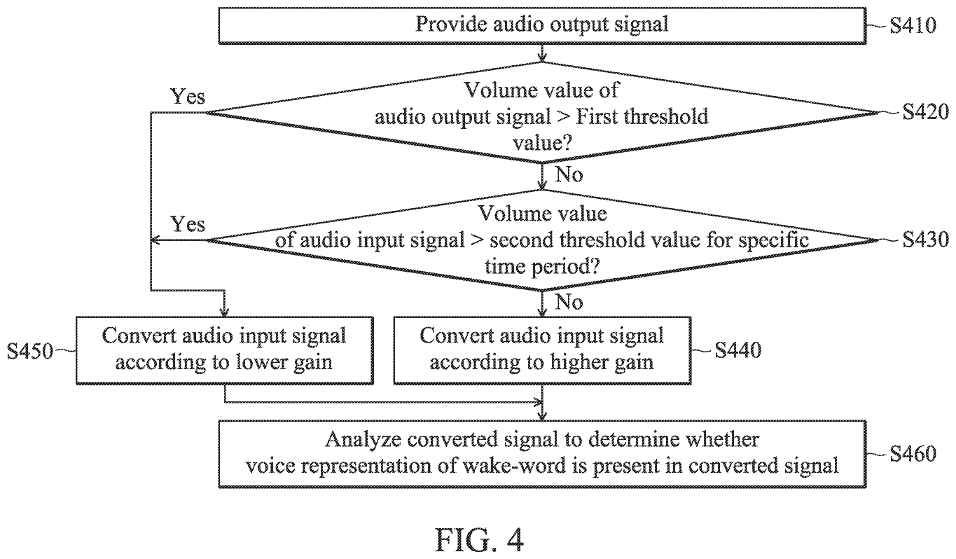

FIG. 4 shows a voice wakeup detecting method 400 for detecting a wake-word according to some embodiment of the invention. In some embodiments, the voice wakeup detecting method 400 of FIG. 4 is performed by an electronic device (e.g., the voice wakeup detecting device 300 of FIG. 3) having a signal processing path for an audio input signal, and the signal processing path is provided by single analog-to-digital converter (e.g., the analog-to-digital converter 320 of FIG. 3).

In step S410, the electronic device is configured to operate in a playing mode, so as to provide (or play) an audio output signal Sout with a volume value VOL via at least one speaker.

In step S420, it is determined whether the output volume value VOL of the audio output signal Sout is greater than the threshold value VOLth_out. If the output volume value VOL is greater than the threshold value VOLth_out, the audio input signal Sin is converted into the signal S5 according to the gain Gain_3 having a lower gain value (step S450).

If the output volume value VOL is less than or equal to the threshold value VOLth_out, it is determined whether the input volume value of the audio input signal Sin is greater than the threshold value VOLth_in during a specific time period (e.g., 1 second) (step S430). If the input volume value of the audio input signal Sin is greater than the threshold value VOLth_in for the specific time period, the audio input signal Sin is converted into the signal S5 according to the gain Gain_3 having the lower gain value (step S450). If the input volume value of the audio input signal Sin is less than or equal to the threshold value VOLth_in, the audio input signal Sin is converted into the signal S5 according to the gain Gain_3 having a higher gain value (step S440)

In step S460, the signal S5 is analyzed to recognize whether voice representation of wake-word is present in the signal S5. In some embodiments, before analyzing the signal S5, one or more pre-processing operations (e.g., NR and AEC) are performed on the signal S5, so as to improve the wake-word recognition rate.

If the voice representation of wake-word is recognized, it is determined that the audio input signal Sin corresponding the wake-word is received by the electronic device, and then the operation corresponding to the wake-word is performed by the electronic device.

In some embodiments, the voice wakeup detecting method 400 of FIG. 4 is performed by an electronic device (e.g., the voice wakeup detecting device 100 of FIG. 1) having at least two signal processing paths for an audio input signal, and each signal processing path is provided by the respective analog-to-digital converter (e.g., the analog-to-digital converters 120_1 and 120_2 of FIG. 1). For example, when the output volume value VOL of the audio output signal Sout is greater than the threshold VOLth_out (step S420) or the input volume value of the audio input signal Sin is greater than the threshold VOLth_in for a specific time period (step S430), the high dynamic range control module 130 is configured to provide the signal EN_1 to disable the analog-to-digital converter 120_1 (i.e., the analog-to-digital converter 120_1 is configured to stop converting the audio input signal Sin into the signal S1 according to the gain Gain_1) and provide the signal EN_2 to enable the analog-to-digital converter 120_2 (step S450). As described above, the gain Gain_1 of the analog-to-digital converter 120_1 is greater than the gain Gain_2 of the analog-to-digital converter 120_2. Thus, the audio input signal Sin from the microphone 10 is converted into the signal S2 according to the gain Gain_2 having the lower gain value, and no signal S1 is provided by the analog-to-digital converter 120_1. Next, the high dynamic range control module 130 is configured to provide the signal S3 only according to the signal S2. Next, the signal S3 is analyzed to recognize whether voice representation of wake-word is present in the signal S3 (step S460).

Conversely, when the output volume value VOL of the audio output signal Sout is less than or equal to the threshold VOLth_out (step S420) and the input volume value of the audio input signal Sin is less than the threshold VOLth_in for the specific time period (step S430), the high dynamic range control module 130 is configured to provide the signal EN_2 to disable the analog-to-digital converter 120_2 (i.e., the analog-to-digital converter 120_2 is configured to stop converting the audio input signal Sin into the signal S2 according to the gain Gain_2) and provide the signal EN_1 to enable the analog-to-digital converter 120_1 (step S440). Thus, the audio input signal Sin from the microphone 10 is converted into the signal S1 according to the gain Gain_1 with a higher gain value by the analog-to-digital converter 120_1, and no signal S2 is provided by the analog-to-digital converter 120_2. Next, the high dynamic range control module 130 is configured to provide the signal S3 only according to the signal SL. Next, the signal S3 is analyzed to recognize whether voice representation of wake-word is present in the signal S3 (step S460).

According to the voice wakeup detecting devices and the voice wakeup detecting methods in the embodiments, the audio input signal Sin is received and converted into the digital signal with a high dynamic range by using multiple gains and/or multiple weights, thereby improving voice wake-up performance.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A voice wakeup detecting device, comprising:
a microphone configured to receive an audio input signal, wherein the audio input signal comprises a voice signal and an ambient voice signal:
a first analog-to-digital converter (ADC) configured to convert the audio input signal into a first signal according to a first gain:
a second analog-to-digital converter configured to convert the audio input signal into a second signal according to a second gain; and
a control module configured to merge the first signal multiplied by a first weight and the second signal multiplied by a second weight into a third signal, and to adjust the first weight and the second weight in response to a volume value,
wherein the second gain is less than the first gain, and the first weight is different than the second weight.

2. The voice wakeup detecting device as claimed in claim 1, further comprising:
a speaker configured to provide at least a part of the ambient voice signal.

3. The voice wakeup detecting device as claimed in claim 1, wherein the control module is configured to enable or disable the first analog-to-digital and the second analog-to-digital according to the volume value of the ambient voice signal.

4. The voice wakeup detecting device as claimed in claim 2, wherein the control module is configured to adjust the first weight and the second weight according to the volume value of the speaker or the ambient voice signal.

5. The voice wakeup detecting device as claimed in claim 1, wherein when the volume value exceeds a threshold value, the first weight is less than the second weight, and when the volume value does not exceed the threshold value, the first weight is greater than the second weight.

6. The voice wakeup detecting device as claimed in claim 1, wherein when the volume value is less than or equal to a threshold value, the control module is configured to disable the second analog-to-digital, and when the volume value is greater than the threshold value, the control module is configured to disable the first analog-to-digital.

7. The voice wakeup detecting device as claimed in claim 1, further comprising:
a wake-word detecting module configured to analyze the third signal to determine whether voice representation of a wake-word is present in the third signal.

8. The voice wakeup detecting device as claimed in claim 1, wherein the second gain has a fixed gain value, and the first gain has a variable gain value.

9. The voice wakeup detecting device as claimed in claim 1, wherein when the volume value exceeds a threshold value, the control module is configured to decrease the first gain.

10. The voice wakeup detecting device as claimed in claim 1, wherein the first weight and the second weight are complex weights applied to a specific frequency sub-band of the audio input signal.

11. A voice wakeup detecting device, comprising:
a microphone configured to receive an audio input signal, wherein the audio input signal comprises a voice signal and an ambient voice signal;
a speaker configured to provide an audio output signal as at least a part of the ambient voice signal;
a control module configured to provide a variable gain in response to a volume value of the audio output signal; and
an analog-to-digital converter (ADC) configured to convert the audio input signal into a first signal according to the variable gain having a first gain value when the volume value of the audio output signal is less than or equal to a first threshold value,
wherein the control module is configured to provide a second signal according to the first signal corresponding to the first gain value.

12. The voice wakeup detecting device as claimed in claim 11, wherein when the volume value of the audio output signal is greater than the first threshold value, the control module is configured to provide the variable gain with a second gain value to the analog-to-digital, and the second gain value is less than the first gain value.

13. The voice wakeup detecting device as claimed in claim 11, wherein the control module is further configured to detect a volume value of the audio input signal, and when the volume value of the audio input signal is greater than a second threshold value for a specific time period, the control module is configured to provide the variable gain with a second gain value to the analog-to-digital, and the second gain value is less than the first gain value.

14. The voice wakeup detecting device as claimed in claim 13, wherein the analog-to-digital is configured to convert the audio input signal into the first signal according to the variable gain having the second gain value, and the control module is configured to provide the second signal according to the first signal corresponding to the second gain value.

15. The voice wakeup detecting device as claimed in claim 9, further comprising:
a wake-word detecting module configured to analyze the second signal to determine whether voice representation of a wake-word is present in the second signal.

16. A voice wakeup detecting method for detecting a wake-word, comprising:
obtaining an audio input signal via a microphone, wherein the audio input signal comprises a voice signal and an ambient voice signal;
obtaining a first weight and a second weight according to a volume value;
converting the audio input signal into a first signal according to a first gain, and multiplying the first signal by the first weight;
converting the audio input signal into a second signal according to a second gain, and multiplying the second signal by the second weight;
merging the first signal multiplied by the first weight and the second signal multiplied by the second weight into a third signal; and
analyzing the third signal to determine whether voice representation of the wake-word is present in the third signal,
wherein the first gain is different than the second gain.

17. The voice wakeup detecting method as claimed in claim 16, further comprising:
providing an audio output signal, by a speaker, as at least a part of the ambient voice signal.

18. The voice wakeup detecting method as claimed in claim 16, wherein the first gain is greater than the second gain, wherein the first weight is less than the second weight when the volume value exceeds a threshold value, and the first weight is greater than the second weigh when the volume value does not exceed the threshold value.

19. The voice wakeup detecting method as claimed in claim 16, further comprising:
adjusting the first weight and the second weight in response to the volume value; and
adjusting the first gain and the second gain in response to the volume value, wherein the first gain is greater than the second gain.

20. The voice wakeup detecting method as claimed in claim 16, further comprising:
stop converting the audio input signal into the second signal according to the second gain when the volume value is less than or equal to a threshold value; and
stop converting the audio input signal into the first signal according to the first gain when the volume value is greater than the threshold value.
